(19) United States
(12) Patent Application Publication
(10) Pub. No.: US 2025/0028942 A1
(43) Pub. Date: Jan. 23, 2025

(54) STRUCTURED SYNTHETIC DATA GENERATION SYSTEM AND METHOD

(71) Applicant: HARBIN INST. OF TECH (SHENZHEN) (INST. OF SCIENCE AND TECH INNOVATION, HARBIN INST. OF TECH), Guangdong (CN)

(72) Inventors: Chuanyi LIU, Guangdong (CN); Peiyi HAN, Guangdong (CN); Shaoming DUAN, Guangdong (CN); Liang YAN, Guangdong (CN)

(73) Assignee: HARBIN INST. OF TECH (SHENZHEN) (INST. OF SCIENCE AND TECH INNOVATION, HARBIN INST. OF TECH), Guangdong (CN)

(21) Appl. No.: 18/900,950

(22) Filed: Sep. 30, 2024

(30) Foreign Application Priority Data
Sep. 7, 2022 (CN) 202211086686.1

(51) Int. Cl. G06N 3/0475; G06N 3/045; G06N 3/047; G06N 3/08

(52) U.S. Cl. CPC G06N 3/0475; G06N 3/045; G06N 3/047; G06N 3/08

(57) ABSTRACT

Disclosed are a structured synthetic data generation system and method. The structured synthetic data generation system comprises a data preprocessing unit and a training and generation unit. The data preprocessing unit is used for transforming each sample in original data into a vector representation and modeling a Bayesian network for describing a relation between features during the transformation process. The training and generation unit is used for training by means of the vector representation transformed from the original data to obtain a synthetic data generation model and generating a synthetic data record by means of the synthetic data generation model. The system and method provided by the invention can simultaneously generate synthetic data records including continuous features and discrete features; generated synthetic data are identical in data distribution and the relation between features with original data.

### CROSS-REFERENCE TO RELATED APPLICATIONS

This application is a continuation of International Application No. PCT/CN2022/135325, filed on Nov. 30, 2022, which claims priority to Chinese patent application No. 202211086686.1, filed on Sep. 7, 2022. The disclosures of the above-mentioned applications are hereby incorporated by reference in their entireties.

### BACKGROUND OF THE INVENTION

### 1. Technical Field

The application relates to the field of computer technology, in particular to a structured synthetic data generation system and method.

### 2. Description of Related Art

In this age of big data, the value of data is obtained generally through data circulation and analysis, which are often accompanied by the risk of privacy disclosure. For structured data, traditional data anonymization techniques protect privacy as desired, and attackers having other data source knowledge are likely to infer anonymized identifiers or quasi-identifiers (the attackers can launch a re-identification attack); and the data anonymization techniques can greatly reduce the availability of data. To balance the availability and privacy of data, a solution of replacing original data with synthetic data is proposed, and only the synthetic data are used during data circulation and analysis. In this way, (1) each record in the synthetic data will not correspond to any entity in reality, thus protecting the privacy of data to the maximum extent; and (2) high-quality synthetic data can be used for analysis like original data, thus reserving the data analysis effect.

As for the generation of synthetic data, Patent Publication No. CN107886009B provides a big-data generation method and system for preventing privacy disclosure. According to the big-data generation method, the probability distribution of each feature is calculated in sequence, all generated features are mutually independent, and the joint probability distribution of obtained synthetic data is not definitely consistent with the joint probability distribution of original data; moreover, the method can only generate synthetic data records including discrete features. Patent Publication No. CN110287729A provides a data synthesis method. However, the data synthesis method cannot generate synthetic data records under specific conditions according to specific application scenarios; moreover, the possible relation between discrete data and continuous data is not taken into account during the data processing process. Patent Publication No. CN110377725B provides a data generation method and device, computer equipment and a storage medium. However, the data generation method can only generate synthetic data records including semantic text information, cannot generate synthetic data records under specific conditions according to specific application scenarios, let along synthetic data records that can be applied more extensively and comprise both discrete features and continuous features. Patent Publication No. CN109376862A provides a time sequence generation method based on a generative adversarial network. However, the time sequence generation method cannot generate synthetic data records under specific conditions according to specific application scenarios and cannot guarantee the consistency in the relation between features of generated synthetic data and original data.

To sum up, existing synthetic data generation methods have the following defects: it is difficult to guarantee the consistency in the joint probability distribution of generated synthetic data and original data; the consistency in the relation between features of generated synthetic data and original data cannot be guaranteed; two types of variables, discrete features and continuous features, cannot be processed simultaneously; and synthetic data records under specific conditions cannot be generated according to specific application scenarios.

### BRIEF SUMMARY OF THE INVENTION

In view of the above problems, the invention provides a structured synthetic data generation system and method to guarantee the consistency in the joint probability distribution of generated synthetic data and original data and the consistency in the relation between features of generated synthetic data and original data, simultaneously process two types of variables, discrete features and continuous features, and generate synthetic data records under specific conditions according to specific application scenarios.

In a first aspect, the invention provides a structured synthetic data generation system, comprising:
a data preprocessing unit and a training and generation unit, wherein the data preprocessing unit is used for transforming each sample in original data into a vector representation and modeling a Bayesian network for describing a relation between features during the transformation process; the training and generation unit is used for training by means of the vector representation transformed from the original data to obtain a synthetic data generation model and generating a synthetic data record by means of the synthetic data generation model;
wherein, the data preprocessing unit comprises a feature discretization module, a relation modeling module and a feature vector transformation module; the feature discretization module is used for discretizing a continuous feature to output a discretization result and information of the continuous feature lost during the discretization process; the relation modeling module is used for modeling the Bayesian network for describing the relation between features according to the discretization result input thereto; the feature vector transformation module is used for transforming the discretization result and the information of the continuous feature lost during the discretization process output by the feature discretization module into the vector representation by encoding and splicing;
the training and generation unit comprises a generation model training module, a generation model generation module and a feature vector back-transformation module; the generation model training module is used for training a structured synthetic data generation model based on a generative adversarial network by means of the vector representation transformed from the original data; the generation model generation module is used for generating a synthetic data vector representation reserving the relation between features by means of the trained synthetic data generation model and the Bayesian network output by the relation modeling module; the feature vector back-transformation module is used for transforming the synthetic data vector representation into a synthetic data record identical in structure with the original data.

Further, the feature discretization module discretizes the continuous feature specifically as follows: a variable value of the continuous feature is mapped into a value range, boundaries of value ranges into which the continuous feature is to be mapped are determined by means of a Gaussian mixture model, and a value of the continuous feature is mapped into the corresponding value range.

Further, the relation modeling module models the Bayesian network for describing the relation between features specifically as follows: for the discretization result input to the relation modeling module, a relational structure between features is modeled by means of a connected directed acyclic graph; for features having a relation therebetween, the relation between the features is quantized by means of conditional probabilities of children node features under the condition that values of parent node features are given; for each feature A, all parent node features PA of the feature A are obtained according to the relational structure, all value combinations of the parent node features are calculated, the probability of all values of the feature A under each value combination is calculated to obtain a conditional probability table of the feature A; and when the conditional probability tables of all the features are calculated, the Bayesian network formed by the directed acyclic graph indicating the relational structure between the features and the conditional probability tables of the features is obtained.

Further, the feature vector transformation module transforms the discretization result and the information of the continuous feature lost during the discretization process output by the feature discretization module into the vector representation by encoding and splicing specifically as follows: the discretization results of all features are subjected to One-Hot encoding and then spliced to obtain a vector form of the discretization results of the features; and the information of the continuous feature lost during the discretization process is directly spliced with the vector form of the discretization results of the features to obtain the vector representation.

Further, the synthetic data generation model comprises a generator and a discriminator, wherein inputs of the generator comprise a noise vector and a condition vector, the noise vector is sampled from multivariate Gaussian distribution, the condition vector is the discretization result vector representation output by the feature discretization module, an output of the generator is the possible loss information during the discretization process, and the possible loss information and the condition vector are spliced to obtain the vector representation of the synthetic data record; inputs of the discriminator comprise the vector representation output after the original data is transformed by the feature vector transformation module and the output of the generator, and the discriminator compares a discrimination result with a true result to optimize discrimination performance; and the generator improves the quality of synthetic data based on the discrimination result to generate stimulation data records closer to true data record distribution.

Further, the generation model generation module generates the synthetic data vector representation reserving the relation between features by means of the trained synthetic data generation model and the Bayesian network output by the relation modeling module specifically as follows: a topological sort of the features is calculated according to the directed acyclic graph in the Bayesian network, a discretization result of each feature is selected in sequence in terms of the probabilities in the conditional probability table according to the topological sort and transformed into a discretization result vector representation, which is then input to the generator of the synthetic data generation model, and the generator outputs the synthetic data vector representation.

Further, in a case where a condition of desired synthetic data is input to the generator, the condition input to the generator is selected directly when a value of a discretization result of a feature node corresponding to the input condition is selected, the discretization results of all features are obtained finally and transformed into a discretization result vector representation, which is then input to the generator of the synthetic data generation model, and the generator outputs the synthetic data vector representation.

Further, the information of the continuous feature lost during the discretization process is specifically expressed as:

$${loss\_info}_{i}^{I} = \frac{{x}_{i}^{I} - mean ( {X}_{I} ) - min ( {X}_{I} )}{max ( {X}_{I} ) - min ( {X}_{I} )}$$

where, loss_infoᵢ^{I} denotes lost information of an i^{th} variable value mapped into a value range I, xᵢ^{I} denotes the i^{th} variable value in the value range I, and mean(X_{I}), min(X_{I}) and max(X_{I}) are a mean value, a minimum value and a maximum value of all variable values mapped into the value range I.

Further, the feature vector back-transformation module transforms the synthetic data vector representation into the synthetic data record identical in structure with the original data specifically as follows:

One-Hot codes in the synthetic data vector representation are transformed into discretization results of features, and a specific variable value of the continuous feature is retrieved according to the information of the continuous feature lost during the discretization process; for a value range I of a continuous feature, an i^{th} variable value mapped into the value range I is denoted as xᵢ^{I}, which is specifically expressed as:

$${x}_{i}^{I} = {loss\_info}_{i}^{I} \times ( max ( {X}_{I} ) - min ( {X}_{I} ) ) + min ( {X}_{I} ) + mean ( {X}_{I} )$$

where, loss_infoᵢ^{I} denotes lost information of the i^{th} variable value mapped into the value range I, and mean(X_{I}), min(X_{I}) and max(X_{I}) are a mean value, a minimum value and a maximum value of all variable values mapped into the value range I.

In a second aspect, the invention provides a structured synthetic data generation method, comprising:
a step of transforming each sample in original data into a vector representation and modeling a Bayesian network for describing a relation between features during the transformation process, which specifically comprises: discretizing, by means of a feature discretization module, a continuous feature to output a discretization result and information of the continuous feature lost during the discretization process; modeling, by means of a relation modeling module, the Bayesian network for describing the relation between features according to the discretization result input to the relation modeling module; and transforming, by means of a feature vector transformation module, the discretization result and the information of the continuous feature lost during the discretization process output by the feature discretization module into the vector representation by encoding and splicing; and
a step of performing training by means of the vector representation transformed from the original data to obtain a synthetic data generation model and generating a synthetic data record by means of the synthetic data generation model, which specifically comprises: performing training by means of a generation model training module using the vector representation transformed from the original data to obtain a structured synthetic data generation model based on a generative adversarial network; generating, by means of a generation model generation module, a synthetic data vector representation reserving the relation between features based on the trained synthetic data generation model and the Bayesian network output by the relation modeling module; and transforming, by means of a feature vector back-transformation module, the synthetic data vector representation into a synthetic data record identical in structure with the original data.

The structured synthetic data generation system and method provided by the invention are a high-quality synthetic data generation system and method based on the Bayesian network and the generative adversarial network and can generate synthetic data which are highly approximate to original data in analysis effect; and the invention innovatively combines the Bayesian network and the generative adversarial network to generate high-quality synthetic data under specified conditions, wherein the Bayesian network is used for describing the relation between features in original data, and the generative adversarial network is used for learning the distribution of the original data. To sum up, the invention has the following beneficial effects: the system and method provided by the invention can simultaneously generate synthetic data records including continuous features and discrete features; as for the quality of synthetic data generated by the system and method provided by the invention, the synthetic data are consistent with original data in data distribution and the relation between features; and the structured synthetic data generation system and method provided by the invention can generate synthetic data according to desired conditions and can generate synthetic data records required for analysis according to different synthetic data application scenarios.

### BRIEF DESCRIPTION OF THE SEVERAL VIEWS OF THE DRAWINGS

FIG. 1 is a schematic structural diagram of a structured synthetic data generation system according to one embodiment of the invention;

FIG. 2 is a schematic diagram of a discretization process of a continuous feature according to one embodiment of the invention;

FIG. 3 is a schematic diagram of a relational structure between features according to one embodiment of the invention.

### DETAILED DESCRIPTION OF THE INVENTION

The invention is described in further detail below in conjunction with accompanying drawings and embodiments. It can be understood that the specific embodiments described here are merely used for explaining the invention and are not intended to limit the invention. In addition, it should be noted that to facilitate the description, only structures related to the invention rather than all structures are shown in the figures.

Before the illustrative embodiments are discussed in further detail, it should be noted that some illustrative embodiments are described as a process or method illustrated by a flow diagram. Although the steps are described in order in the flow diagram, many of these steps may be performed parallelly, concurrently or synchronously. In addition, the order of the steps can be reset. The process may be ended when the steps are performed, or the process may comprise additional steps that are not shown in the flow diagram. The process may correspond to a method, a function, a routine, a subroutine, a subprocess or the like.

The invention provides the following embodiments for a structured synthetic data generation system and method.

### Embodiment 1 Based on the Invention

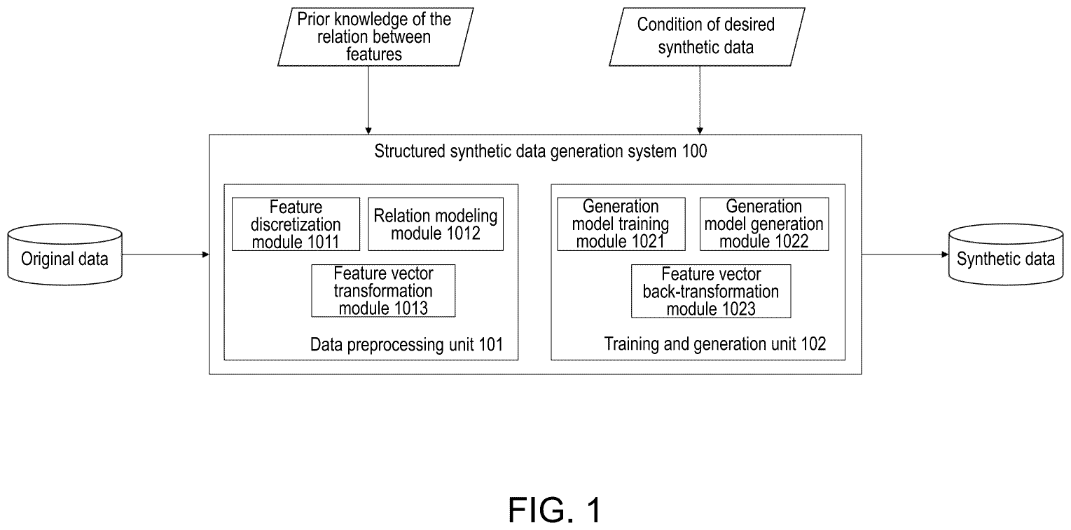

As shown in FIG. 1, Embodiment 1 of the invention provides a structured synthetic data generation system 100, comprising a data preprocessing unit 101 and a training and generation unit 102, wherein the data preprocessing unit 101 is used for transforming each sample in original data into a vector representation and modeling a Bayesian network for describing a relation between features during the transformation process; the training and generation unit 102 is used for training by means of the vector representation transformed from the original data to obtain a synthetic data generation model and generating a synthetic data record by means of the synthetic data generation model; wherein, the data preprocessing unit 101 comprises a feature discretization module 101, a relation modeling module 1012 and a feature vector transformation module 1013; the feature discretization module 1011 is used for discretizing a continuous feature to output a discretization result and information of the continuous feature lost during the discretization process; the relation modeling module 1012 is used for modeling the Bayesian network for describing the relation between features according to the discretization result input thereto; the feature vector transformation module 1013 is used for transforming the discretization result and the information of the continuous feature lost during the discretization process output by the feature discretization module 1011 into the vector representation by encoding and splicing; the training and generation unit 102 comprises a generation model training module 1021, a generation model generation module 1022 and a feature vector back-transformation module 1023; the generation model training module 1021 is used for training a structured synthetic data generation model based on a generative adversarial network by means of the vector representation transformed from the original data; the generation model generation module is used for generating a synthetic data vector representation reserving the relation between features by means of the trained synthetic data generation model and the Bayesian network output by the relation modeling module 1012; the feature vector back-transformation module 1023 is used for transforming the synthetic data vector representation into a synthetic data record identical in structure with the original data.

As shown in FIG. 1, the structured synthetic data generation system 100 has three inputs, which are original data, prior knowledge of the relation between features (optional input), and a condition of desired synthetic data.

In specific implementation, the original data are structured data and comprise a plurality of data records, and each data record has a plurality of features. For example, for a student grade dataset storing information of students in a class, each record corresponds to the information of one student and records corresponding values of features such as the number, name and grade of all subjects of the student. During data mining and analysis, only discrete features and continuous features concern in most cases. The discrete feature is a feature, a variable value set of which is a finite set, such as gender or native place. The continuous feature is a feature, a variable value of which is a value within a value range, such as age or grade. Other fields of analytic significance other than the discrete features and the continuous features generally can be divided into combinations of the discrete features and the continuous features. For example, an address feature can be divided into combinations of a plurality of discrete features such as province and city. On this basis, the structured data generation system 100 only aims at discrete features and continuous features in original data and can generate synthetic data identical with original data in the number and types of features.

As shown in FIG. 1, the prior knowledge of the relation between features is an optional input, that is, the data owner has the cognition of the relation between data features. For example, the data owner may perceive that there is a relation between the seniority and the salary and the salary will become higher with the increase of the seniority. In addition to the input prior knowledge, the Bayesian network is also used by the structured synthetic data generation system to model the relation between features, which is combined with the prior knowledge to automatically (without the prior knowledge) or semi-automatically (with the prior knowledge) learn the relation between features.

As shown in FIG. 1, the condition of desired synthetic data is also an optional input and refers to the requirement for the values of some features in the synthetic data. For example, synthetic data of records of samples, the gender of which is male and the monthly salary of which is greater than 5000, need to be generated. In some data analysis scenarios, synthetic data of features, the values of which are specified, are needed. For example, if the seniority distribution of samples, the gender of which is male and the monthly salary of which is greater than 5000, needs to be analyzed, only synthetic data records meeting the condition that the gender is male and the monthly salary is greater than 5000 are needed.

After obtaining the inputs, the system outputs high-quality synthetic data by means of the data preprocessing unit 101 and the training and generation unit 102.

The data preprocessing unit 101 is used for transforming each sample in the original data into the vector representation and modeling the Bayesian network for describing the relation between features during the transformation process. The data preprocessing unit 101 comprises three modules, which are a feature discretization module 1011, a relation modeling module 1012 and a feature vector transformation module 1013 respectively.

Preferably, the feature discretization module 1011 discretizes the continuous feature specifically as follows: a variable value of the continuous feature is mapped into a value range, boundaries of value ranges into which the continuous feature is to be mapped are determined by means of a Gaussian mixture model, and a value of the continuous feature is mapped into the corresponding value range.

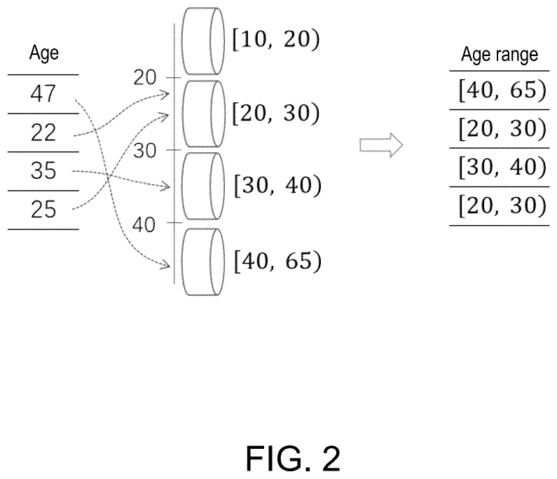

As shown in FIG. 2, the specific implementation is as follows: the feature discretization module 1011 discretizes the continuous feature, that is, a variable value of the continuous feature is mapped into a value range. Boundaries of value ranges to which the continuous feature is to be mapped are determined by means of a Gaussian mixture model, and then a value of the continuous feature is mapped into the corresponding value ranges. For example, if the value of the age feature in a data record is 22, the value will be mapped into the value range [20, 30). Because this mapping process may lead to a loss of information of the continuous feature, the information of the continuous feature lost in the discretization process needs to be recorded.

Specifically, the discretization process is as follows: for a continuous feature C, the variable distribution of the continuous feature Cis fit first by means of a Gaussian mixture model with k Gaussian components, as shown in FIG. 2, and the variable distribution (continuous line) of the age feature can be divided into four Gaussian components (dotted lines). Then the value ranges are determined with a maximum value of the feature, a maximum value of the feature, and the intersection of distribution functions of every two Gaussian components with the maximum probability as division points. As shown in FIG. 2, in a case where the maximum value of the age feature is 10, the maximum value of the age feature is 65 and division points determined by the Gaussian mixture model are 20, 30 and 40, four value ranges [10, 20), [20, 30), [30, 40) and [40, 65] are obtained, and the age feature is mapped into the corresponding value range.

Further, because the specific value information of the feature may be lost in the discretization process of the continuous feature, for example, as shown in FIG. 2-1, the values 22 and 25 of the feature are both mapped into the value range [20,30), so the variable cannot be mapped back to the specific value anymore from the corresponding value range, the lost information needs to be recorded. Preferably, the information of the continuous feature lost in the discretization process is specifically expressed as:

$${loss\_info}_{i}^{I} = \frac{{x}_{i}^{I} - mean ( {X}_{I} ) - min ( {X}_{I} )}{max ( {X}_{I} ) - min ( {X}_{I} )}$$

where, loss_infoᵢ^{I} denotes lost information of an i^{th} variable value mapped into a value range I, denotes the i^{th} variable value in the value range I, and mean(X_{I}), min(X_{I}) and max(X_{I}) are a mean value, a minimum value and a maximum value of all variable values mapped into the value range I.

Finally, the feature discretization module 1011 outputs a discretization result of the feature (a discrete feature itself is a discretization result, and the continuous feature needs to undergo the discretization process) and information of the continuous feature lost in the discretization process.

Preferably, the relation modeling module 1012 models the Bayesian network for describing the relation between features specifically as follows: for the discretization result input to the relation modeling module 1012, a relational structure between features is modeled by means of a connected directed acyclic graph; for features having a relation therebetween, the relation between the features is quantized by means of conditional probabilities of children node features under the condition that values of parent node features are given; for each feature A, all parent node features PA of the feature A are obtained according to the relational structure, all value combinations of the parent node features are calculated, the probability of all values of the feature A under each value combination is calculated to obtain a conditional probability table of the feature A; and when the conditional probability tables of all the features are calculated, the Bayesian network formed by the directed acyclic graph indicating the relational structure between the features and the conditional probability tables of the features is obtained.

In specific implementation, the relation modeling module 1012 models the Bayesian network for describing the relation between features, and inputs of the relation modeling module 1012 are the discretization result (one output of the feature discretization module 1011) and the prior knowledge of the relation between features (optional input).

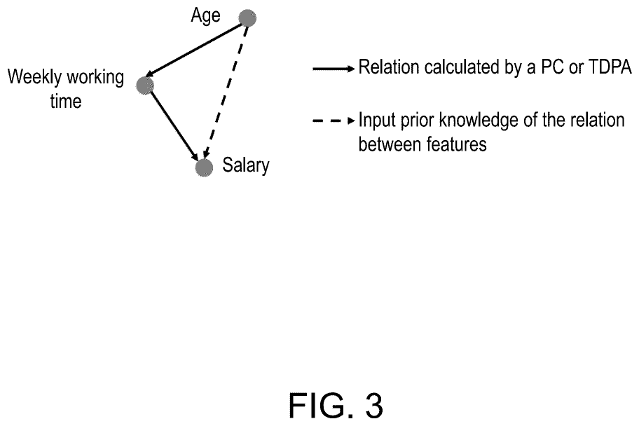

Specifically, as shown in FIG. 3, the relational structure between features may be indicated by a connected directed acyclic graph, wherein nodes in the graph indicate features, and a directed edge between the nodes indicates the relation between the features. For example, there is a relation between the seniority and the salary, and the seniority often determines the salary (the salary depends on the seniority), so there will be a directed edge between the node indicating the seniority and the node indicating the salary in a directed acyclic graph indicating the relation between the features, and the directed edge points from the node indicating the seniority and the node indicating the salary. The relation modeling module 1012 obtains the directed acyclic graph describing the relation between the features by a PC or TPDA; and if the prior knowledge of the relation between feature is input, a directed edge corresponding to the prior knowledge is added to the obtained directed acyclic graph. As shown in FIG. 3, in a dataset comprising three features which are age, weekly working time and salary, a relational structure between the age determining the weekly working time, the weekly working time determining the salary, and the salary is obtained by the PC or TPDA, the prior knowledge that the age determines the salary is input, so the relation indicated by the directed acyclic graph is that the age determines the weekly working time and determines the salary together with the weekly working time.

Specifically, for a structured data table T comprising n features A₁, A₂, . . . , Aₙ and having each feature Aᵢ corresponding to a node Vᵢ in a directed acyclic graph, if a direct parent node set of Vᵢ is SVₚₐᵣₑₙₜₛ₍ᵢ₎ (that is, for any Vᵢ∈SVₚₐᵣₑₙₜₛ₍ᵢ₎, Vⱼ→Vᵢ), it indicates that the feature Aᵢ depends on a feature set SAₚₐᵣₑₙₜₛ₍ᵢ₎ corresponding to the node set SVₚₐᵣₑₙₜₛ₍ᵢ₎; similarly, if the direct parent node set of Vᵢ is SV_{children(i)} (that is, for any Vₖ∈SV_{children(i)}, Vᵢ→Vₖ), it indicates, that a feature set SA_{children(i)} corresponding to the node set SV_{children(i)} depends on the feature Aᵢ.

After the relational structure between features is modelled, the relation modeling module 1012 needs to specifically quantize such a relation: for features having a relation therebetween, the relation between the features can be quantized by means of conditional probabilities of children node features under the condition that values of parent node features are given. For example, there is a relation between the seniority and the salary, the probability that the monthly salary of people, whose seniority is over 20 years, is greater than 10,000 is 0.8, and the probability that the monthly salary of people, whose seniority is less than 20 years, is greater than 10,000 is 0.3.

In a case where the features having a relation therebetween are all discrete features, value probabilities of children node features in a parent node feature set can be calculated to obtain a conditional probability table. In a case where there is a continuous feature in a feature set, features in which have a relation therebetween, it will make no sense to calculate the conditional probability because the probability of any variable value in a probability density function of the continuous feature is 0. Therefore, when the conditional probability table corresponding to the relation between features including a continuous feature, the value of the continuous feature should be a range rather than an accurate value, so the relation modeling module 1012 quantizes the relation between features by calculation based on the feature discretization result output by the feature discretization module 1011. For each feature A, all parent node features PA of the feature A are obtained by means of the relational structure, all value combinations of the parent nodes are calculated, and then the probability of all values of the feature A under each combination is calculated and recorded to obtain a conditional probability table of the feature A. When the conditional probability tables of all the features are calculated, the Bayesian network formed by the directed acyclic graph indicating the relation between the features and the conditional probability tables of the features is obtained and is used as an output of the relation modeling module 1012.

Further, the feature vector transformation module 1013 transforms the discretization result and the information of the continuous feature lost during the discretization process output by the feature discretization module 1011 into the vector representation by encoding and splicing specifically as follows: the discretization results of all features are subjected to One-Hot encoding and then spliced to obtain a vector form of the discretization results of the features; and the information of the continuous feature lost during the discretization process is directly spliced with the vector form of the discretization results of the features to obtain the vector representation.

In specific implementation, the feature vector transformation module 1013 transforms each data record into a vector form, which can be input to a neural network later. The input of the feature vector transformation module 1013 is the output of the feature discretization module 1011 (the discretization result and the information of the continuous feature lost in the discretization process).

In the discretization result of the features, the variable value of each feature is discrete (the discrete feature will not be processed, and the variable value of the continuous feature will be mapped into a value range), and One-Hot encoding is performed. Specifically, for the discretization result Dᵢ of an i^{th} feature, there are Nᵢ discrete variable values in total, the Nᵢ discrete variable values are sorted, the code of a j^{th} value is [0, . . . ,0,1,0, . . . ,0], the length of the code is Nᵢ, a j^{th} element in the code is 1, and the other element in the code are all 0. The discretization results of all the features are encoded and then spliced to obtain a vector form of the discretization results of the features; and the information of the continuous feature lost during the discretization process is continuous and thus can be directly spliced with the vector form of the discretization results of the features to obtain the vector representation.

Further, the training and generation unit 102 performs training by means of the vector form transformed from the original data to obtain a synthetic data generation model used for generating high-quality synthetic data records identical in structure with the original data in use. The training and generation unit 102 comprises three modules which are respectively a generation model training module 1021, a generation model generation module 1022 and a feature vector back-transformation module 1023.

Wherein, the generation model training module 1021 is used for training a structured synthetic data generation model based on a generative adversarial network, and an input of the generation model training module 1021 is the vector representation transformed from the original data. The structured synthetic data generation model comprises a generator and a discriminator, and the generator and the discriminator are both neural network models. The generator is configured to generate synthetic data records as true as possible, and the discriminator is configured to discriminate whether input data are from the original data or from the generator. The generator and the discriminator are trained and used together, the generator improves the generation quality, and the discriminator improves the discrimination capacity.

Specifically, the generator has two inputs, which are a noise vector and a condition vector respectively. The noise vector is sampled from multivariate Gaussian distribution and aims to improve the stochasticity of the inputs of the generator to diversify the output of the generator, such that the generator will not generate the same synthetic data records in case of the same inputs. The condition vector is the vector form of the discretization results of the features and can be considered as the “condition” of generated synthetic data records because it specifies the values of all discrete features and the value ranges of continuous features. After the inputs are processed by the neural network of the generator, the information of the continuous feature that may be lost in the discretization process is output and spliced with the condition vector to obtain a vector representation of one synthetic data record.

The input of the discriminator is the vector representation of a complete data record and is the output obtained after the original data are transformed by the feature vector transformation unit or the output of the generator. After the input is processed by the neural network of the discriminator, a discrimination result of the vector representation of the data record is output. The discriminator compares the discrimination result with a true result to optimize the discrimination performance; and the generator improves the quality of synthetic data based on the discrimination result to generate synthetic data records closer to true data record distribution. Finally, the generation model training module 1021 outputs a trained generator neural network model.

Preferably, the synthetic data generation model 1022 comprises a generator and a discriminator, which are both neural network models, inputs of the generator comprise a noise vector and a condition vector, the noise vector is sampled from multivariate Gaussian distribution, the condition vector is the discretization result vector representation output by the feature discretization module 1011, an output of the generator is the possible loss information during the discretization process, and the possible loss information and the condition vector are spliced to obtain the vector representation of the synthetic data record; inputs of the discriminator comprise the vector representation output after the original data is transformed by the feature vector transformation module 1013 and the output of the generator, and the discriminator compares a discrimination result with a true result to optimize discrimination performance; and the generator improves the quality of synthetic data based on the discrimination result to generate stimulation data records closer to true data record distribution.

Further, the generation model generation module 1022 generates the synthetic data vector representation reserving the relation between features by means of the trained synthetic data generation model and the Bayesian network output by the relation modeling module 1012 specifically as follows: a topological sort of the features is calculated according to the directed acyclic graph in the Bayesian network, a discretization result of each feature is selected in sequence in terms of the probabilities in the conditional probability table according to the topological sort and transformed into a discretization result vector representation, which is then input to the generator of the synthetic data generation model, and the generator outputs the synthetic data vector representation.

Further, in a case where a condition of desired synthetic data is input to the generator, the condition input to the generator is selected directly when a value of a discretization result of a feature node corresponding to the input condition is selected, the discretization results of all features are obtained finally and transformed into a discretization result vector representation, which is then input to the generator of the synthetic data generation model, and the generator outputs the synthetic data vector representation.

In specific implementation, the generation model generation module 1022 generates a synthetic data record reserving the relation between features by means of a generator neural network model output by the generation model training module 1021 and the Bayesian network output by the relation modeling module 1012. Therefore, the generator output by the generation model training module 1021 is input to the generation model generation module 1022, and the Bayesian network and the condition of desired synthetic data (optional input) are output by the relation modeling module 1012.

Inputs of the generator comprise a noise vector and a condition vector, the noise vector is sampled from multivariate Gaussian distribution, and the condition vector indicates the condition of synthetic data to be generated by the generator and is determined by the Bayesian network and the condition of desired synthetic data jointly. First, the topological sort of the features is calculated according to the directed acyclic graph in the Bayesian network, a discretization result of each feature is selected in sequence in terms of the probabilities in the conditional probability table according to the topological sort. Because of the characteristic that in the topological sort, a parent node of a feature is certainly prior to a node corresponding to the feature, the discretization result of the feature indicated by parent node has been determined when the value of the discretization result of the feature is selected. If the condition of desired synthetic data is input, the value of the discretization result of a feature node corresponding to the give condition will not be selected according to the probability in the conditional probability table, and the input condition will be selected directly. Finally, values of the discretization results of all features are obtained and follow the relation in the original data. The results are subjected to One-Hot encoding and then input to the generator as the condition vector to guide the generator to generate synthetic data records following the relation in the original data. Possible loss information of the continuous feature during the discretization process is output by the generator and spliced with the condition vector to obtain a complete vector form of a synthetic data record, which is used as an output of the generation model generation module 1022.

Specifically, if a data set comprises three features which are age, weekly working time and salary and the age determines the weekly working time and determines the salary together with the weekly working time, the topological sort of the data set is: age, weekly working time and salary. The discretization result of the feature indicated by each node is selected in sequence according to the topological sort in terms of the conditional probability table. Then, the results are subjected to One-Hot encoding and then input to the generator as the condition vector, the noise vector sampled from multivariate Gaussian distribution is input to the generator, the generator outputs possible loss information of the continuous feature during the discretization process, and the possible loss information is spliced with the condition vector to obtain a vector form of a synthetic data record.

Further, the feature vector back-transformation module 1023 is used for transforming the synthetic data vector representation into the synthetic data record identical in structure with the original data, and an input of the feature vector back-transformation module 1023 is the complete vector form of the synthetic data record. The feature vector back-transformation module 1023 essentially an inverse process of the data processing process. Specifically:

One-Hot codes in the synthetic data vector representation are transformed into discretization results of features, and a specific variable value of the continuous feature is retrieved according to the information of the continuous feature lost during the discretization process; for a value range/of a continuous feature, an i^{th} variable value mapped into the value range/is denoted as xᵢ^{I}, which is specifically expressed as:

$${x}_{i}^{I} = {loss\_info}_{i}^{I} \times ( max ( {X}_{I} ) - min ( {X}_{I} ) ) + min ( {X}_{I} ) + mean ( {X}_{I} )$$

where, loss_infoᵢ^{I} denotes lost information of the i^{th} variable value mapped into the value range I, and mean(X_{I}), min(X_{I}) and max(X_{I}) are a mean value, a minimum, value and a maximum value of all variable values mapped into the value range I.

Finally, the feature vector back-transformation module 1023 outputs a synthetic data record including continuous features and discrete feature.

The structured synthetic data generation system provided by this embodiment can guarantee the consistency in the joint probability distribution of generated synthetic data and original data and the consistency in the relation between features of generated synthetic data and original data, can simultaneously process two types of variables, discrete features and continuous features, and can generate synthetic data records under specific conditions according to specific application scenarios.

### Embodiment 2 Based on the Invention

Embodiment 2 of the invention provides a structured synthetic data generation method, specifically comprising:

a step of transforming each sample in original data into a vector representation and

modeling a Bayesian network for describing a relation between features during the transformation process, which specifically comprises: discretizing, by means of a feature discretization module, a continuous feature to output a discretization result and information of the continuous feature lost during the discretization process; modeling, by means of a relation modeling module, the Bayesian network for describing the relation between features according to the discretization result input to the relation modeling module; and transforming, by means of a feature vector transformation module, the discretization result and the information of the continuous feature lost during the discretization process output by the feature discretization module into the vector representation by encoding and splicing; and a step of performing training by means of the vector representation transformed from the original data to obtain a synthetic data generation model and generating a synthetic data record by means of the synthetic data generation model, which specifically comprises: performing training by means of a generation model training module using the vector representation transformed from the original data to obtain a structured synthetic data generation model based on a generative adversarial network; generating, by means of a generation model generation module, a synthetic data vector representation reserving the relation between features based on the trained synthetic data generation model and the Bayesian network output by the relation modeling module; and transforming, by means of a feature vector back-transformation module, the synthetic data vector representation into a synthetic data record identical in structure with the original data.

The structured synthetic data generation method may be based on the structured synthetic data generation system in Embodiment 1. Therefore, the specific operating process of the structured synthetic data generation method may be understood with reference to the description of the structured synthetic data generation system in Embodiment 1 and will not be repeated here.

The structured synthetic data generation system and method in the above embodiments are a high-quality synthetic data generation system and method based on the Bayesian network and the generative adversarial network and can generate synthetic data which are highly approximate to original data in analysis effect; and the invention innovatively combines the Bayesian network and the generative adversarial network to generate high-quality synthetic data under specified conditions, wherein the Bayesian network is used for describing the relation between features in original data, and the generative adversarial network is used for learning the distribution of the original data. To sum up, the invention has the following beneficial effects: the system and method provided by the invention can simultaneously generate synthetic data records including continuous features and discrete features; as for the quality of synthetic data generated by the system and method provided by the invention, the synthetic data are consistent with original data in data distribution and the relation between features; and the structured synthetic data generation system and method provided by the invention can generate synthetic data according to desired conditions and can generate synthetic data records required for analysis according to different synthetic data application scenarios.

It should be noted that the above description merely explains the preferred embodiments and technical principle of the invention. Those skilled in the art should understand that the invention is not limited to the specific embodiments described here and can make various obvious transformations, readjustments and substitutions without departing from the protection scope of the invention. Therefore, although the invention is described in detail with reference to the above embodiments, the invention is not limited to the above embodiments and may include more other equivalent embodiments without departing from the concept of the invention, and the scope of the invention is defined by the Appended Claims.

What is claimed is:

1. A structured synthetic data generation system, comprising a data preprocessing unit and a training and generation unit, wherein the data preprocessing unit is used for transforming each sample in original data into a vector representation and modeling a Bayesian network for describing a relation between features during the transformation process; the training and generation unit is used for training by means of the vector representation transformed from the original data to obtain a synthetic data generation model and generating a synthetic data record by means of the synthetic data generation model;
wherein, the data preprocessing unit comprises a feature discretization module, a relation modeling module and a feature vector transformation module; the feature discretization module is used for discretizing a continuous feature to output a discretization result and information of the continuous feature lost during the discretization process; the relation modeling module is used for modeling the Bayesian network for describing the relation between features according to the discretization result input thereto; the feature vector transformation module is used for transforming the discretization result and the information of the continuous feature lost during the discretization process output by the feature discretization module into the vector representation by encoding and splicing;
the training and generation unit comprises a generation model training module, a generation model generation module and a feature vector back-transformation module; the generation model training module is used for training a structured synthetic data generation model based on a generative adversarial network by means of the vector representation transformed from the original data; the generation model generation module is used for generating a synthetic data vector representation reserving the relation between features by means of the trained synthetic data generation model and the Bayesian network output by the relation modeling module; the feature vector back-transformation module is used for transforming the synthetic data vector representation into a synthetic data record identical in structure with the original data.

2. The structured synthetic data generation system according to claim 1, wherein the feature discretization module discretizes the continuous feature specifically as follows: a variable value of the continuous feature is mapped into a value range, boundaries of value ranges into which the continuous feature is to be mapped are determined by means of a Gaussian mixture model, and a value of the continuous feature is mapped into the corresponding value range.

3. The structured synthetic data generation system according to claim 1, wherein the relation modeling module models the Bayesian network for describing the relation between features specifically as follows: for the discretization result input to the relation modeling module, a relational structure between features is modeled by means of a connected directed acyclic graph; for features having a relation therebetween, the relation between the features is quantized by means of conditional probabilities of children node features under the condition that values of parent node features are given; for each feature A, all parent node features PA of the feature A are obtained according to the relational structure, all value combinations of the parent node features are calculated, the probability of all values of the feature A under each value combination is calculated to obtain a conditional probability table of the feature A; and when the conditional probability tables of all the features are calculated, the Bayesian network formed by the directed acyclic graph indicating the relational structure between the features and the conditional probability tables of the features is obtained.

4. The structured synthetic data generation system according to claim 1, wherein the feature vector transformation module transforms the discretization result and the information of the continuous feature lost during the discretization process output by the feature discretization module into the vector representation by encoding and splicing specifically as follows: the discretization results of all features are subjected to One-Hot encoding and then spliced to obtain a vector form of the discretization results of the features; and the information of the continuous feature lost during the discretization process is directly spliced with the vector form of the discretization results of the features to obtain the vector representation.

5. The structured synthetic data generation system according to claim 3, wherein the synthetic data generation model comprises a generator and a discriminator, inputs of the generator comprise a noise vector and a condition vector, the noise vector is sampled from multivariate Gaussian distribution, the condition vector is the discretization result vector representation output by the feature discretization module, an output of the generator is the possible loss information during the discretization process, and the possible loss information and the condition vector are spliced to obtain the vector representation of the synthetic data record; inputs of the discriminator comprise the vector representation output after the original data is transformed by the feature vector transformation module and the output of the generator, and the discriminator compares a discrimination result with a true result to optimize discrimination performance; and the generator improves the quality of synthetic data based on the discrimination result to generate stimulation data records closer to true data record distribution.

6. The structured synthetic data generation system according to claim 5, wherein the generation model generation module generates the synthetic data vector representation reserving the relation between features by means of the trained synthetic data generation model and the Bayesian network output by the relation modeling module specifically as follows: a topological sort of the features is calculated according to the directed acyclic graph in the Bayesian network, a discretization result of each feature is selected in sequence in terms of the probabilities in the conditional probability table according to the topological sort and transformed into a discretization result vector representation, which is then input to the generator of the synthetic data generation model, and the generator outputs the synthetic data vector representation.

7. The structured synthetic data generation system according to claim 6, wherein in a case where a condition of desired synthetic data is input to the generator, the condition input to the generator is selected directly when a value of a discretization result of a feature node corresponding to the input condition is selected, the discretization results of all features are obtained finally and transformed into the discretization result vector representation, which is then input to the generator of the synthetic data generation model, and the generator outputs the synthetic data vector representation.

8. The structured synthetic data generation system according to claim 1, wherein the information of the continuous feature lost during the discretization process is specifically expressed as:
$${loss\_info}_{i}^{I} = \frac{{x}_{i}^{I} - mean ( {X}_{I} ) - min ( {X}_{I} )}{max ( {X}_{I} ) - min ( {X}_{I} )}$$
where, loss_infoᵢ^{I} denotes lost information of an i^{th} variable value mapped into a value range I, xᵢ^{I} denotes the i^{th} variable value in the value range I, and mean(X_{I}), min(X_{I}) and max(X_{I}) are a mean value, a minimum value and a maximum value of all variable values mapped into the value range I.

9. The structured synthetic data generation system according to claim 1, wherein the feature vector back-transformation module transforms the synthetic data vector representation into the synthetic data record identical in structure with the original data specifically as follows:
One-Hot codes in the synthetic data vector representation are transformed into discretization results of features, and a specific variable value of the continuous feature is retrieved according to the information of the continuous feature lost during the discretization process; for a value range I of a continuous feature, an i^{th} variable value mapped into the value range I is denoted as xᵢ^{I}, which is specifically expressed as:
$${x}_{i}^{I} = {loss\_info}_{i}^{I} \times ( max ( {X}_{I} ) - min ( {X}_{I} ) ) + min ( {X}_{I} ) + mean ( {X}_{I} )$$
where, loss_infoᵢ^{I} denotes lost information of the i^{th} variable value mapped into the value range I, and mean(Xᵢ^{I}), min(Xᵢ^{I}), and max(X_{I}) are a mean value, a minimum value and a maximum value of all variable values mapped into the value range I.

10. A structured synthetic data generation method, comprising:
a step of transforming each sample in original data into a vector representation and modeling a Bayesian network for describing a relation between features during the transformation process, which specifically comprises: discretizing, by means of a feature discretization module, a continuous feature to output a discretization result and information of the continuous feature lost during the discretization process; modeling, by means of a relation modeling module, the Bayesian network for describing the relation between features according to the discretization result input to the relation modeling module; and transforming, by means of a feature vector transformation module, the discretization result and the information of the continuous feature lost during the discretization process output by the feature discretization module into the vector representation by encoding and splicing; and
a step of performing training by means of the vector representation transformed from the original data to obtain a synthetic data generation model and generating a synthetic data record by means of the synthetic data generation model, which specifically comprises: performing training by means of a generation model training module using the vector representation transformed from the original data to obtain a structured synthetic data generation model based on a generative adversarial network; generating, by means of a generation model generation module, a synthetic data vector representation reserving the relation between features based on the trained synthetic data generation model and the Bayesian network output by the relation modeling module; and transforming, by means of a feature vector back-transformation module, the synthetic data vector representation into a synthetic data record identical in structure with the original data.
